(19) United States
(12) Patent Application Publication
(10) Pub. No.: US 2026/0016544 A1
(43) Pub. Date: Jan. 15, 2026

(54) METHOD AND APPARATUS FOR MAPPING ENERGY STORAGE MODULE LOCATION IN A MODULAR BATTERY ENERGY STORAGE SYSTEM

(71) Applicant: Enphase Energy, Inc., Petaluma, CA (US)

(72) Inventors: Vikram Nandakumar IYENGAR, Austin, TX (US); Jonathan List EHLMANN, Austin, TX (US); Chris Morrow YOUNG, Round Rock, TX (US); Daniel John O’NEILL, Christchurch (NZ)

(21) Appl. No.: 19/265,121

(22) Filed: Jul. 10, 2025

Related U.S. Application Data
(60) Provisional application No. 63/669,750, filed on Jul. 11, 2024.

(51) Int. Cl. G01R 31/396; G01R 31/367; G01R 31/3835; H01M 10/42; H01M 50/251; H01M 50/298

(52) U.S. Cl. CPC G01R 31/396; G01R 31/367; G01R 31/3835; H01M 10/4221; H01M 10/425; H01M 50/251; H01M 50/298; H01M 2010/4278; H01M 2220/10

(57) ABSTRACT

A method and apparatus for mapping energy storage module locations in a modular battery energy storage system. The apparatus comprises a plurality of energy storage modules, arranged in an array within a frame, for storing energy and electrically connected to at least one wiring harness to interconnect the plurality of energy storage modules. The plurality of energy storage modules are coupled to an energy storage module mapping system for determining a physical location of each energy storage module within the array of energy storage modules based upon signals from the energy storage modules.

### RELATED APPLICATION

This application claims the benefit of U.S. Provisional Application No. 63/669,750, filed Jul. 11, 2024, entitled “Method and Apparatus for Mapping Battery Module Location in a Modular Battery Energy Storage System,” the entire contents of which are hereby incorporated by reference.

### BACKGROUND

### Field

Embodiments of the present invention generally relate to energy storage systems and, in particular, to a method and apparatus for mapping energy storage module location in a modular battery energy storage system.

### Description of the Related Art

Energy storage systems for storing electrical energy have found widespread use in renewable energy systems. To smooth the availability of energy from distributed energy resources (e.g., solar panels, wind turbines, etc.), energy storage systems store electrical energy when excess energy is generated by the distributed resources and supply energy when the resources cannot supply energy (e.g., at night, light wind, etc.). In addition, energy storage systems may store energy supplied by a power grid to either source power when power is unavailable from distributed sources or the power grid, or source power to supplement the grid power during periods of peak demand.

One form of energy storage system uses energy storage modules arranged in an array to store electrical energy. A battery energy storage system (BESS) typically comprises a plurality of energy storage modules (also known as battery modules) that are rack mounted to form an array. Installation of a BESS is difficult and time-consuming. After installation or during installation, the installers must generate a map of energy storage module locations such that return merchandise authorization (RMA) processing and/or repair processing can be directed to each unique module.

Typically, once wired, the installer must inventory the energy storage module array to manually identify each module and its location by scanning a unique bar code for each module or noting the unique module serial number as well as identifying each module location in the array and in the facility, if more than one array exists. This manual procedure is prone to error.

Therefore, there is a need for a method and apparatus for automatically mapping energy storage module location in a modular battery energy storage system.

### SUMMARY

A method and apparatus for mapping energy storage module location in a modular battery energy storage system is provided substantially as shown in and/or described in connection with at least one of the figures, as set forth more completely in the claims.

Various features and advantages of the present disclosure may be appreciated from a review of the following detailed description of the present disclosure, along with the accompanying figures in which like reference numerals refer to like parts throughout.

### BRIEF DESCRIPTION OF THE DRAWINGS

So that the manner in which the various features of the present invention can be understood in detail, a particular description of the invention, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a perspective view of a modular battery energy storage system having a energy storage module mapping system in accordance with at least one embodiment of the invention;

FIG. 2 depicts a perspective, exploded view of the battery energy storage system of FIG. 1 in accordance with at least one embodiment of the invention;

FIG. 3 depicts a schematic of a energy storage module mapping system in accordance with at least one embodiment of the invention;

FIG. 4 depicts a schematic of a energy storage module mapping system using a resistor network in accordance with at least one alternative embodiment of the invention;

FIG. 5 depicts a schematic of a energy storage module mapping system using a resistor network in accordance with at least one alternative embodiment of the invention;

FIG. 6 depicts an exploded view of a energy storage module having a magnet-based energy storage module mapping system in accordance with at least one embodiment of the invention;

FIG. 7 depicts a schematic of a energy storage module mapping system using a sensor network in accordance with at least one alternative embodiment of the invention; and

FIG. 8 depicts a block diagram of a controller programmed to perform energy storage module mapping in accordance with at least one embodiment of the invention.

### DETAILED DESCRIPTION

Embodiments of the present invention comprise a modular, scalable battery energy storage system. The system comprises a mounting frame that may be attached to a wall or other supporting surface and a plurality of energy storage modules attached to and supported by the frame. Each module comprises a modular battery pack and at least one modular power conditioning unit (PCU). Embodiments are described as storing energy in battery packs-the term battery should be broadly construed as an form of rechargeable, electrical energy storage device including, but not limited to, capacitors, super-capacitors, all forms of rechargeable battery (e.g., Lithium-ion, metal-hydride, nickel-cadmium, lead-acid, Lithium iron phosphate, Sodium-ion, Lithium polymer and the like), superconducting magnetic storage, or combinations thereof.

The modules are typically arranged vertically as an array within the frame. In some embodiments, the modules may be arranged in a two-dimensional array (i.e., multiple vertical columns of modules). Each module slides into the frame along a module support assembly and are retained within the frame. Each module plugs into a prewired, frame mounted wiring harness. A wiring box is positioned, typically, on top of the frame and plugs into the wiring harness. However, the wiring box may also be located in other locations within the array, such as, but not limited to, the middle of the array or the bottom of the array. The facility (home or business) wiring (i.e., a load center) is then coupled to the wiring box.

The battery energy storage system comprises a energy storage module location mapping system having a controller coupled to a plurality of monitoring circuits or devices. Each modular energy storage module comprises a mapping device or circuit for identifying the location of the energy storage module within the frame. The mapping devices may comprise a wiring network built into the wiring harness to measure voltage drop across the modules. In another embodiment, magnets may be positioned on the frame proximate a magnetic field sensor on the energy storage module. The magnets are positioned in a particular order to indicate the location in the array where the energy storage module is located, e.g., top, middle, bottom, or position 1, 2, 3. In a further embodiment, a resistor network is created as each energy storage module is coupled to the wiring harness. The voltage drop across each resistor in the resistor network is monitored by a monitoring device which reports the voltage to the controller. The controller may be local (e.g., in the wiring box) or remote (e.g., in a gateway or in a monitoring station). Using these embodiments, enables the energy storage module locations to be automatically mapped.

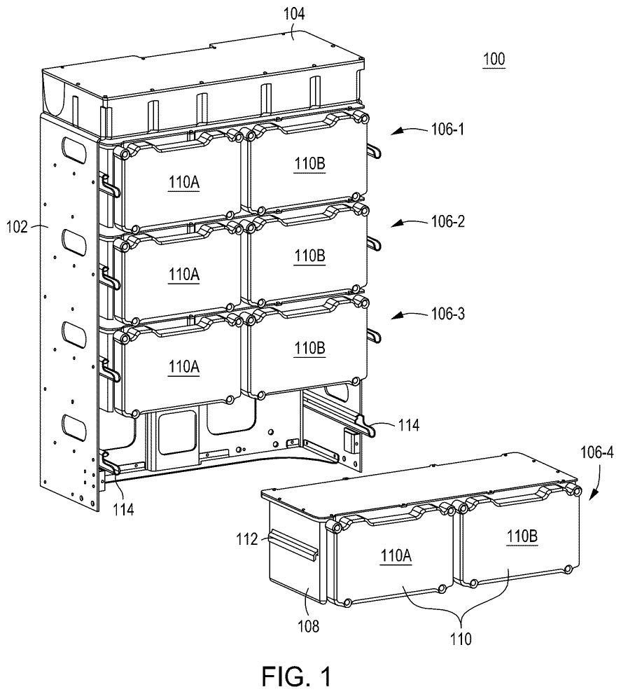

FIG. 1 depicts a perspective view of a battery energy storage system 100 in accordance with at least one embodiment of the invention. The system 100 comprises mounting frame 102, a wiring box 104 and a plurality of energy storage modules 106-1, 106-2, 106-3, 106-4 (collectively referred to as modules 106). Although four modules 106 are shown, the frame 102 may be manufactured in taller or shorter sizes to accommodate any number of modules. In other embodiments, the frame may be manufactured in a wider version to accommodate modules arranged vertically and adjacent to one another (i.e., a two-dimensional array).

Each module 106 comprises a battery pack 108 and at least one power conditioning unit (PCU) 110. In the depicted embodiment, two PCUs 110A and 110B are shown coupled to each battery pack 108. Each battery pack 108 (only one is visible in module 106-4) comprises a plurality of battery cells (not visible in this view). The number of cells may vary depending on the storage capacity of the battery pack. However, a typical battery pack comprises about eight cells electrically connected in series. To enable a single installer to be able to install the BESS 100, the storage modules 106 should weigh about 25 kg or less.

The PCUs 110 are bidirectional power converters that, when operated in a discharge mode, convert DC power from the battery pack 108 into AC power (e.g., 120V to 480V one, two or three phase AC power). Additionally, when operating in a charge mode, the PCUs 110 convert supplied AC power to DC power to charge the battery pack 108. Each PCU 110 has a maximum power rating. In one embodiment, each PCU has a power rating of about 650 W.

The modules 106 comprises a pair of module support rails 112 (one rail 112 on each side of the module 106) that is adapted to slide upon and be supported by a complimentary frame rail 114 located on the side of the frame 102. The combination of a module support rail 112 and a frame rail 114 form a module support assembly. Once positioned in the frame 102, the modules 106 are bolted to the frame using a module retainer.

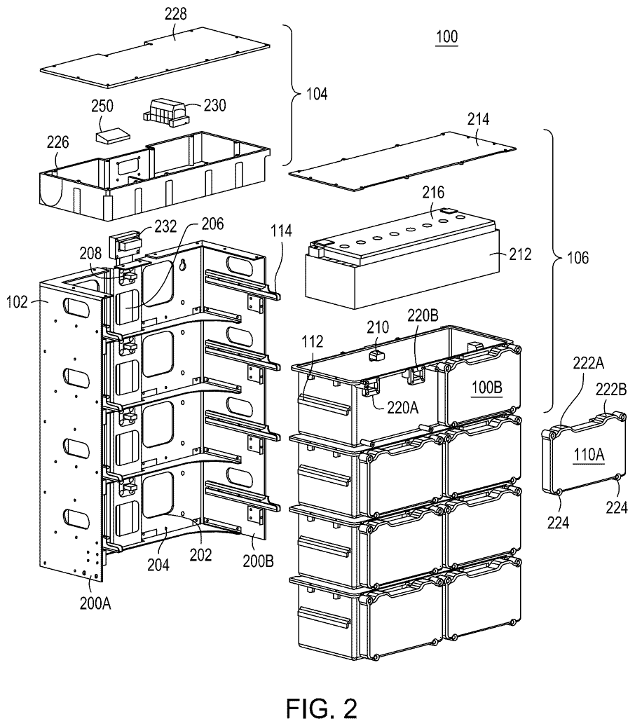

As each module 106 is slid into the frame, a plug on the rear of the module 106 electrically connects to a complementary plug in a wiring harness on the back of the frame 102, as describe with respect to FIG. 2 below. The wiring box 104 is located on the top of the frame 102 and electrically connects to the wiring harness. The wiring box 104 is designed to couple the BESS 100 to a load center such that the stored energy may be used to power loads in a facility.

FIG. 2 depicts a perspective, exploded view of the BESS 100 of FIG. 1 in accordance with at least one embodiment of the invention. As described above, the BESS 100 comprises a frame 102, a wiring box 104 and at least one storage module 106. In one embodiment, the frame 102 comprises a pair of side walls 200A and 200B that extend at right angles from a rear wall 202. The side walls 200A and 200B comprise frame rails 114 that are adapted to interact with module support rails 112 to support the modules 106 within the frame 102. Four stiffening brackets 204 are mounted to the rear and sidewalls 200A, 200B and 202 to stiffen the frame 102. The brackets 204 are mounted periodically and spaced to be located between the energy storage modules 106 along the vertical height of the frame 102. The frame 102 supports a wiring harness 206 that has a connector 208 aligned with each module 106 to provide a communications connection, location mapping connection and a power connection. In one embodiment, communications are provided via a controller area network (CAN) bus. In other embodiments, communications are provided by a power line communications (PLC) bus, i.e., the power connection carries communications signals. In further embodiments, other wired communications protocols may be used including, but not limited to, universal serial bus (USB), universal asynchronous receiver/transmitter (UART), serial peripheral interface (SPI), and the like. The wiring harness 206 also communicates module identification and location information from the modules 106 to a controller 250 located in the wiring box 104.

In the depicted embodiment, the wiring box 104 is located at the top of the stack of modules 106. In other embodiments, the wiring box 104 may be positioned in other locations in place of a module 106, i.e., position the wiring box 104 in the center of the stack with a number of modules 106 above and below the wiring box 104.

Each module 106 comprises a connector 210 that is complementary to the connector 208 to create a module power and communications connection. As such, the AC power flows to/from the modules 106 via the wiring harness 206. The communications connection couples each module 106 to a battery management unit (BMU) which may be located remotely from the BESS 100. In some embodiments, the BMU is collocated within the BESS 100 as part of the controller 250 and may be located in the BESS energy storage modules 106 or wiring box 104. For example, the BMU may be the controller 250. The wiring harness 208 may include wiring for one, two and/or three phase configurations for the BESS 100. For example, the wiring harness may be wired to accommodate one or more of, but are not limited to, US 240V split phase, EU 230V single phase, US 208/120V 3 phase, US 480/277 V 3phase, and/or US 208/120V two phase.

In one exemplary embodiment, the modules 106 comprise an open topped box 212, a lid 214 and a battery pack 216. The battery pack 216 resides inside the box 212. The battery pack 216 comprises a plurality of battery cells (not specifically shown) and various circuitry (not shown) for monitoring at least one battery pack parameter including, but not limited to, state of charge (SOC) of the cells, the temperature of the cells, voltage levels, current flow and the like. This circuitry may be contained within a local BMU or controller (not shown) in each energy storage module 106. The parameter(s) are communicated from the local BMU/circuitry through the communication connection (e.g., CAN, PLC, etc.) to the BMU/controller 250. The modules 106 are designed to produce 3 phase AC power such that, in one embodiment, the connector 210 comprises three AC power pins (e.g., three phase) and four communications pins (e.g., CAN bus). The wiring harness may vary from application to application of the BESS such that the three phase AC of the module 106 is matched to the desired output (e.g., US 240V split phase, EU 230V single phase, US 208/120V 3 phase, US 480/277 V 3 phase, and/or US 208/120V two phase).

The at least one PCU 110 is electrically connected to the battery pack 218 and the wiring harness 208 via mating connectors 220A, 220B, 222A, 222B. Connectors 220A, 222A carry AC power and communications signals and connectors 220B and 222B couple DC power between the battery pack and the PCU circuitry. The module 106 comprises wiring to couple the AC power and communications signals from connector 220A to the wiring harness connector 210. Each PCU 110 is electrically connected by aligning the mating connectors and pushing the PCU 110 toward the box 212 and then using fasteners 224 (e.g., bolts or screws) to retain the PCU 110 in position. In this manner, the front mounted PCUs may be quickly and easily disconnected and replaced when a PCU fails.

In one embodiment, the wiring box 104 comprises an open box shaped housing 226 and a lid 228. In an alternative embodiment, the wiring box 104 has an open box shaped housing with the front being the opening for access to the wiring box 104. A coupler 230 is coupled to a plug 232 at the top of the wiring harness 208. Facility wiring from, for example, a load center connective wires, are coupled to the coupler 230 to couple communications as well as AC power to the load center and BMU/controller, i.e., the wiring box becomes an interface to the facility wiring.

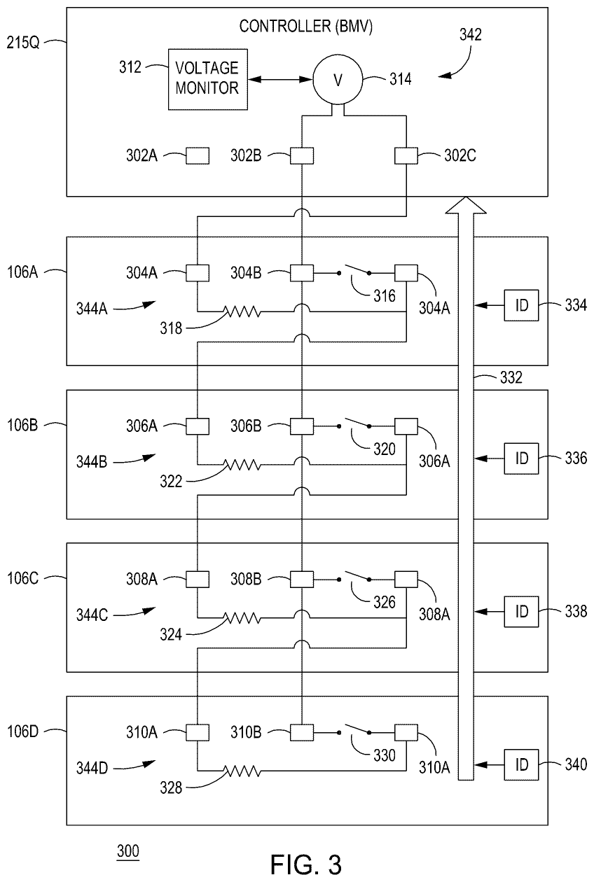

As a portion of a energy storage module location mapping system, each energy storage module 106 also comprises a device and/or circuitry (not shown in FIG. 2, shown and described with respect to FIGS. 3-7 below) that facilitates determining and communicating the location of each module 106 within the frame 102 to the controller 250. As such, each energy storage module generates a signal indicative of the location of the energy storage module that is communicated via the wiring harness 206 to the controller 250 to facilitate location mapping of the energy storage modules 106. In a BESS with two or more stacks of modules (i.e., two-dimensional array) would include a plurality of wiring harnesses, one for each stack.

FIG. 3 depicts a schematic diagram of a energy storage module mapping system 300 in accordance with at least one embodiment of the invention. The system 300 comprises a portion 342 in the controller/BMU 250 within the wiring box 104 and portions within each energy storage module 106A, 106B, 106C, 106D in the local circuitry/BMU 344A, 344B, 344C, and 344D. The controller/BMU circuitry 342 comprises a voltage source 314, a voltage monitor 312 and three pins 302A, 302B and 302C. The voltage source 314 is coupled to pins 302A and 302C. The voltage monitor 312 monitors the voltage drop across pins 302A and 302C.

The pins 302A, 302B and 302C couple to corresponding pins 304A, 304B and 304C located on the energy storage module 106A. Such coupling occurs via the wiring harness (206 of FIG. 2). Within module 106A, mapping circuit 344A comprises a module resistor 318 coupled between pins 304A and 304C and a switch 316 coupled between pins 304A and 304B. Each module 106 comprises a communications bus 332 (such as, for example, a CAN bus or other communications protocol known to those skilled in the art) for coupling a energy storage module identifier (e.g., serial number) 334 to the controller/BMU 250.

In some alternative embodiments, the controller 342 may be combined with mapping circuit 344A within the top energy storage module 106A to facilitate the module 106A becoming a master unit to map the module locations and identifications as described below.

Energy storage modules 106B, 106C and 106D each comprise mapping circuits 344A, 344B, 344C and 344D. Mapping circuit 344B comprises 3 pins 306A, 306B and 306C, module resistor 322, switch 320, communications bus 332, and module identifier (ID) 336. The components of mapping circuit 344B are arranged in the same manner as mapping circuit 344A described above.

Mapping circuit 344C comprises 3 pins 308A, 308B and 308C, module resistor 324, switch 326, communications bus 332, and module identifier (ID) 338. The components of mapping circuit 344C are arranged in the same manner as mapping circuit 344A described above.

Mapping circuit 344D comprises 3 pins 310A, 310B and 310C, module resistor 328, switch 330, communications bus 332, and module identifier (ID) 340. The components of mapping circuit 344D are arranged in the same manner as mapping circuit 344A described above. In operation, the switches 316, 320, 326, 330 are controlled to apply a voltage across each module resistor 318, 322, 324, 328 in a resistor network formed by the series connected module resistors 318, 322, 324, 328.

In operation, the controller/BMU 250 signals energy storage module 106A (typically, using a local controller within the module) to initiate a mapping process that closes the switch 316 and has the module identifier 334 sent on the communications bus 332. When switch 316 closes, a specific voltage drop across the module resistor 218 is measured by the voltage monitor 312. This voltage drop is across a single resistor and provides an indicator that the module is the topmost module. The controller/BMU 250 then logs the location of the module (location A) along with its module identifier 334. Once complete, the process opens switch 316.

Next, module 106B is polled in the same manner. Switch 322 is closed, switch 316 is opened, and resistors 318 and 322 are coupled in series as well as coupled to the voltage source 314, which increases the voltage drop monitored by the voltage monitor 312. The voltage drop indicates that the module being polled is module 106B. The location (location B) and its identifier 336 are logged by the controller/BMU 250.

This process is continued with respect to modules 106C and 106D respectively using switches 326 and 330 to measure voltage drops across the series connected resistors including resistors 324 and 328. The respective locations (locations C and D) are mapped with the identifiers 338 and 340. In this manner. All the module locations are automatically mapped along with the module identifiers such that locating the modules for repairs and RMA processing is simplified and accurate.

In some embodiments, the value of the resistor in each module may not be known to the controller/BMU 250. In this instance, the mapping circuit may supply the resistor value of its respective module to the CAN bus to be sent to the controller/BMU 250 for use in the voltage drop calculation. Additionally, if more module stacks are within the BESS, the controller/BMU 250 addresses each wiring harness of each stack in sequence to map all of the modules within the BESS.

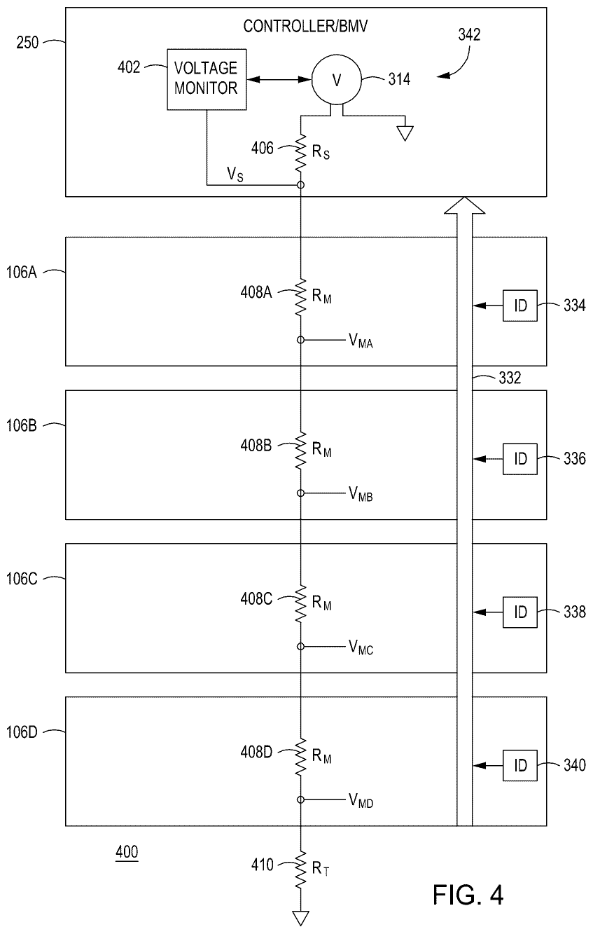

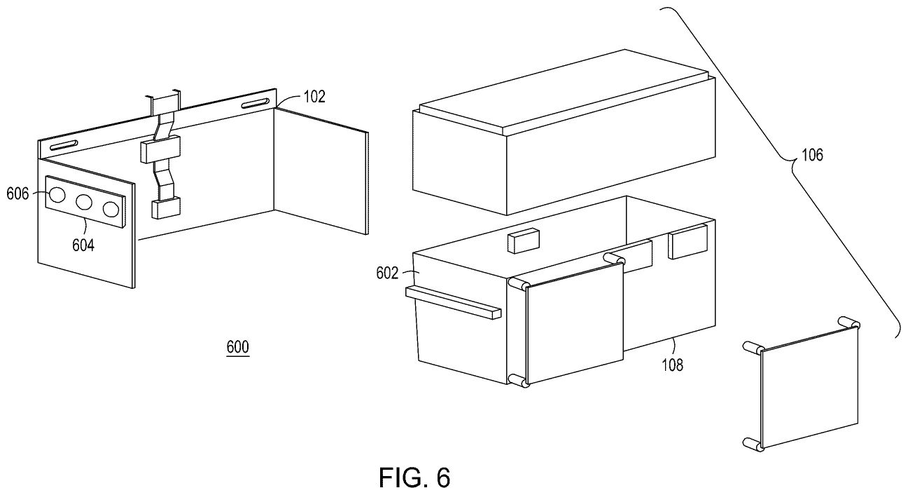

FIG. 4 depicts a energy storage mapping system 400 that uses a resistor network within a wiring harness to determine energy storage module location in accordance with at least one alternative embodiment of the invention. The energy storage mapping system 400 is a simplified version of the system 300 in FIG. 3. Here, the wiring harness (206 of FIG. 6) contains embedded, series connected, resistors (source resistor 406, module resistors 408A-D, and termination resistor 410). The termination resistor may alternatively be a short to ground (i.e., no resistor). The termination resistor (or short) may be attached to the end of the wiring harness as a portion of a dust cover. When a module 106 is connected to the wiring harness, a pin on the harness supplies the voltage V_{M} to ground at the corresponding module resistor R_{M} for measurement by the module 106.

With knowledge of the resistor values and the source voltages, the controller/BMU 250 can compute the number (N) of resistors in the string using the following equation:

$$N = \frac{\frac{\text{?}}{\text{?}} R \text{?} - R \text{?} {R}_{r}}{{R}_{m}}$$

$$\text{?} \text{indicates text missing or illegible when filed}$$

The number of resistors can then be broadcast (i.e., general announcement) from the controller/BMU 250 to all the modules 106 via the communications bus 332. The modules 106 may use the number N to compute their location (i) in the stack using the following equation:

$$i = \frac{\frac{\text{?}}{\text{?}} {( NR + R \text{?} + R \text{?} ) - R \text{?}}_{m}}{{R}_{m}}$$

$$\text{?} \text{indicates text missing or illegible when filed}$$

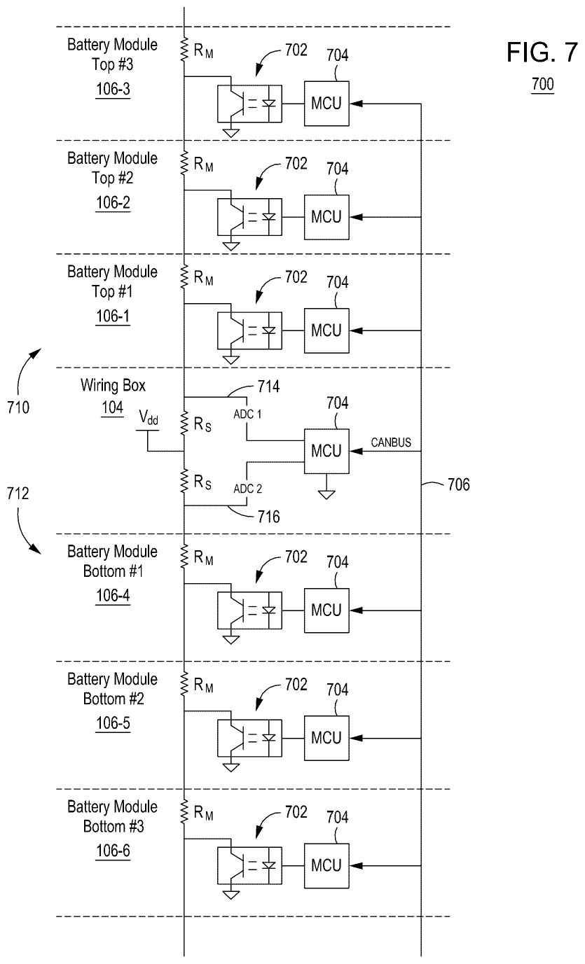

Each module 106 may then send its location and identifier 334, 336, 338, 340 to the controller/BMU 250 via the communications bus 332. Alternatively, the modules 106 may send the measured voltage Vₘ and identifier to the controller/BMU 250 and the controller/BMU 250 may compute the location of each module 106 using the equations above. The computed location may be associated with the respective identifier and stored in a map database (See FIG. 7 for additional details regarding processing hardware).

In a further alternative embodiment, each module 106 may send its measured voltage Vₘ and identifier to the controller/BMU 250. The controller/BMU 250 may then rank the voltages from largest to smallest (e.g., nearer to further from controller/BMU 250) to determine the location of each module 106.

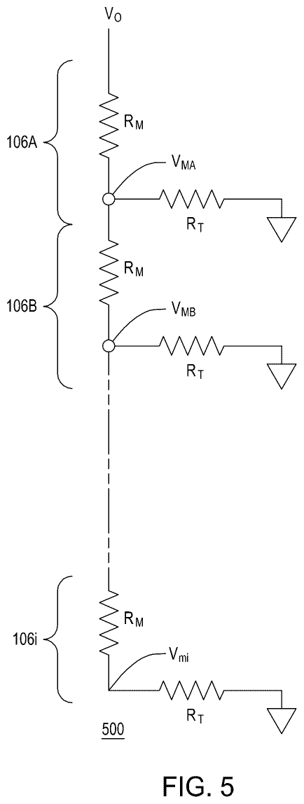

FIG. 5 depicts an alternative energy storage mapping system 500 that uses an alternative resistor network within a wiring harness 332 in accordance with at least one embodiment of the invention. In this embodiment, neither a termination resistor at the end of the string nor a source resistor at the beginning of the string are used. Each module 106 comprises its own termination resistor R_{T} coupled from the series module resistor R_{M} to ground. The measurement voltage V_{M} is measured at the junction of resistors R_{T} and R_{M}. Each module 106 communicates the measured voltage V_{M} and the modules identifier to the controller/BMU 250 via the communications bus (332 in FIGS. 3 and 4). The controller/BMU 250 ranks the voltages from largest to smallest to determine the location of the module 106 in the frame from nearest to the controller/BMU 250 to the furthest (i.e., top of the stack to bottom).

Furthermore, each wiring box (i.e., controller/BMU 250) can be serialized so that the central control system has a unique address for the wiring box and its communication controller. Given an address for the wiring box and the location of a module associated with a wiring box, any module within a residential or commercial location can be uniquely identified. By placing the location identifier within the wiring harness modules can be replaced or moved to alternate location and the addressing automatically changes. Additionally, new modules can be inserted and the addressing can be updated automatically.

FIG. 6 depicts a perspective, exploded view of a portion 600 of the battery energy storage system of FIG. 1 in accordance with at least one embodiment of the invention. In this embodiment, magnets 606 are used on the frame 102 to form a module identifier that assigns a location code for the module in the BESS. The magnets 606 are held in place by a retention feature 604 (e.g., coin slot, clip, adhesive, etc.) and the arrangement is encoded by the installer. Magnets can be binary coded (e.g., 011), linearly encoded (e.g., position 1, 2, 3 . . . ), etc. This magnet positioning creates a location address for where the module 106 is located within the frame 102.

To read the positions of the magnets 606 in the retention feature 604, a magnetic field sensor 602 is attached to a portion (e.g., side) of the module 106. The sensor 602 senses the magnetic field of each magnet and may be, for example, reed switches, Hall Effect, magneto-resistive, and the like. The magnetic field sensor 602 may comprise and array of sensor elements. The magnets/sensors can be located on either side or the back of the module 106. A signal representing the positioning of the magnets 606 is communicated to the controller/BMU. This embodiment establishes a physical relationship between a module address and communication bus address (i.e., module identifier). As in embodiments above, the module address information and module identifier may be sent from the module 106 to the controller/BMU via a CAN bus.

The forgoing embodiments mounted the magnets on the frame and the magnetic field sensor(s) on the energy storage module. Of course, it is equivalent to mount the magnets on the energy storage modules and the magnetic field sensor(s) on the energy storage modules.

FIG. 7 depicts a schematic of a energy storage module mapping system using an sensor network 700 in accordance with at least one alternative embodiment of the invention. In this embodiment, the wiring box 104 is positioned in the center of the energy storage module stack (e.g., energy storage modules 106-1, 106-2, 106-3, 106-4, 106-5, 106-6. The network 700 comprises a plurality of series module resistors R_{M} having one resistor for each energy storage module. Each resistor R_{M} is coupled to an isolator 702 (an opto-isolator or, alternatively, a field effect transistor (FET)) driven by a module control unit (MCU) 704. Each MCU 704 is connected to a communications bus 706 (for example, a CAN bus) that couples to the sensing MCU 708 in the wiring box 104. The sensing MCU 708 couples to the series connected resistors R_{M} via resistors R_{S}. A pair of resistors R_{S} have a first terminal connected together and the connection point is coupled to ground. The second terminal of each resistor R_{S} is respectively coupled to a resistor R_{M} in the upper and lower sets 710 and 712 of energy storage modules 106. The second terminals are also coupled to the sensing MCU 708 and used as sensing terminals 714 and 716.

In operation, the energy storage module MCU 704 controls the FET or isolator 702 via the communications bus 706 to short the series connected resistor R_{M} to ground. The resulting voltage in the resistor network (series connected resistors R_{M}) is digitized and read by the sensing MCU 708. The distance of the energy storage module 106 from the wiring box 104 is proportional to the measured voltage. The two digitized voltages at the sensing terminals 714 and 716 can differentiate between the energy storage modules 106 above 710 and below 712 the wiring box 104 and the specific measured voltage identifies the location of each module in the array. The MCUs 704 sequentially activate their respective isolator to couple their respective resistor to ground. The sensing MCU 708 measures the voltage at terminals 714 and 716 with each sequential activation of an isolator 702.

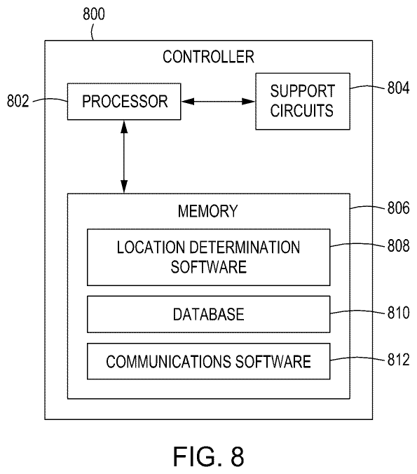

FIG. 8 depicts a block diagram of an exemplary controller used to perform various operations in the energy storage modules (local controller) or the controller/BMU within the wiring box discussed above in accordance with at least one embodiment of the invention. The controller is also referred to as an MCU. The controller 800 comprises at least one processor 802, support circuits 804 and memory 806. The at least one processor 802 may be any form of processor or combination of processors including, but not limited to, central processing units, microprocessors, microcontrollers, field programmable gate arrays, graphics processing units, and the like. The support circuits 804 may comprise well-known circuits and devices facilitating functionality of the processor(s) and its interactions with the energy storage modules. The support circuits 804 may comprise one or more of, or a combination of, power supplies, clock circuits, communications circuits, cache, voltage measurement or monitoring circuits, switch controllers, and/or the like.

The memory 806 comprises one or more forms of non-transitory computer readable media including one or more of, or any combination of, read-only memory or random-access memory. The memory 806 stores software and data including, for example, location determination software 808, communications software 812 and the like. The location determination software 808 contains instructions that when executed by the at least one processor causes the processor to perform the functional operates described above with respect to the controller/BMU 250 and the energy storage modules 106. Such operations include, but are not limited to, measuring voltages, measuring magnet position, communicating information between modules and controllers, determining energy storage module location, storing module locations and identifiers in a database 810, and the like. The communications software 812 facilitates communication using the communication bus (e.g., CAN bus or other communications protocol).

Here multiple examples have been given to illustrate various features and are not intended to be so limiting. Any one or more of the features may not be limited to the particular examples presented herein, regardless of any order, combination, or connections described. In fact, it should be understood that any combination of the features and/or elements described by way of example above are contemplated, including any variation or modification which is not enumerated, but capable of achieving the same. Unless otherwise stated, any one or more of the features may be combined in any order.

As above, figures are presented herein for illustrative purposes and are not meant to impose any structural limitations, unless otherwise specified. Various modifications to any of the structures shown in the figures are contemplated to be within the scope of the invention presented herein. The invention is not intended to be limited to any scope of claim language.

Where conditional language is used, including, but not limited to, “can,” “could,” “may” or “might,” it should be understood that the associated features or elements are not required. As such, where conditional language is used, the elements and/or features should be understood as being optionally present in at least some examples, and not necessarily conditioned upon anything, unless otherwise specified.

Where lists are enumerated in the alternative or conjunctive (e.g., one or more of A, B, and/or C), unless stated otherwise, it is understood to include one or more of each element, including any one or more combinations of any number of the enumerated elements (e.g. A, AB, AC, ABC, ABB, etc.). When “and/or” is used, it should be understood that the elements may be joined in the alternative or conjunctive.

While the foregoing is directed to embodiments of the present invention, other and further embodiments of the invention may be devised without departing from the basic scope thereof, and the scope thereof is determined by the claims that follow.

1. A battery energy storage system comprising:
a plurality of energy storage modules, arranged in an array within a frame, for storing energy and electrically connected to at least one wiring harness to interconnect the plurality of energy storage modules; and
an energy storage module mapping system, coupled to the at least one wiring harness, for determining a physical location of each energy storage module within the array of energy storage modules based upon signals from the energy storage modules.

2. The battery energy storage system of claim 1, wherein the energy storage module mapping system comprises:
a plurality of mapping circuits, where each mapping circuit in the plurality of mapping circuits is configured to measure voltage levels across a resistor within a network of resistors; and
a controller configured to correlate the measured voltage levels with storage module identifiers to determine physical positions of the storage modules within the array.

3. The battery energy storage system of claim 2, wherein each mapping circuit comprises:
a resistor; and
a switch configured to selectively apply a voltage to the resistor in the resistor network.

4. The battery energy storage system of claim 1, wherein each storage module comprises:
a battery pack;
a module identifier; and
a mapping circuit configured to generate the signals indicative of the storage module physical location within the array for a storage module associated with the module identifier.

5. The battery energy storage system of claim 4, wherein the module identifier is an arrangement of magnets attached to the frame and the mapping circuit comprises a magnetic field sensor for sensing the arrangement of the magnets.

6. The battery energy storage system of claim 1, wherein the energy storage module mapping system comprises:
a plurality of magnetic sensors mounted on each of the energy storage modules or on the frame; and
a plurality of magnets arranged at predetermined locations on the frame or one each energy storage module, where the arrangement of magnets corresponds to a position of each energy storage module in the array.

7. The battery energy storage system of claim 1, wherein the energy storage module mapping system comprises:
a plurality of resistors connected in series, having each resistor of the plurality of resistors associated with an energy storage module;
a plurality of isolators, each isolator associated with a particular energy storage module and coupled to a resistor associated with the particular energy storage module;
a plurality of module control units configured to control respective isolators within each energy storage module; and
a sensing module control unit configured to measure voltage levels when each isolator is activated for determining storage module positions.

8. The battery energy storage system of claim 7, wherein the isolator is an opto-isolator or a field effect transistor (FET).

9. The battery energy storage system of claim 1, wherein the at least one wiring harness comprises:
a communication bus connecting each storage module to a controller; and
power connections for connecting the energy storage modules to one another.

10. A method for determining a location of an energy storage module within an array of energy storage modules mounted in a frame, comprising:
generating, at each energy storage module, a signal indicative of the location of the energy storage module in the array; and
communicating the signal to a controller, where the controller determines the location of each energy storage module within the array based on the signal.

11. The method of claim 10, wherein generating the signal comprises:
applying a voltage across a resistor network comprising module resistors associated with the energy storage modules; and
measuring voltage levels at different points in the resistor network, where the measured voltage levels for the signal use to identify the location of each energy storage module within the array.

12. The method of claim 11, further comprising:
selectively activating switches in the energy storage modules to apply voltage to respective module resistors in the resistor network; and
measuring voltage changes resulting from the selective activation of the switches.

13. The method of claim 10, wherein generating the signal comprises:
detecting magnetic field patterns using a magnetic sensor mounted on the energy storage modules or the frame; and
generating the signal indicating the location of each energy storage module based on the detected magnetic field patterns.

14. The method of claim 10, wherein communicating the signal comprises:
transmitting the signal via a communication bus connecting the energy storage modules to the controller; and
transmitting energy storage module identifiers along with the signals indicating the location of each energy storage module within the array.

15. The method of claim 14, further comprising:
correlating the signals with storage module identifiers to determine physical positions of the energy storage modules within the array; and
storing the determined positions in a database.

16. A controller for a battery energy storage system comprising a plurality of energy storage modules arranged in an array within a frame, the controller comprising:
a processor;
non-transitory computer readable media coupled to the processor and storing location determination software;
a communication interface configured to receive, from a plurality of energy storage modules, energy storage module identifiers and location signals from energy storage modules;
wherein the location determination software, when executed by the processor, causes the controller to:
receive signals indicative of a location of each energy storage module within the array and energy storage module identifiers from an energy storage mapping system the energy storage modules;
correlate the signals with the module identifiers to determine physical positions of the energy storage modules within the array; and
store the determined positions in a database.

17. The controller of claim 16, wherein the location determination software further causes the controller to:
apply a voltage across a resistor network comprising module resistors associated with the energy storage modules; and
measure voltage levels at different points in the resistor network, where the measured voltage levels for the signal use to identify the location of each energy storage module within the array.

18. The controller of claim 16, wherein the location determination software further causes the controller to:
selectively activate switches in the energy storage modules to apply voltage to respective module resistors in the resistor network; and
measure voltage changes resulting from the selective activation of the switches.

19. The controller of claim 16, wherein the location determination software further causes the controller to:
detect magnetic field patterns using a magnetic sensor mounted on the energy storage modules or the frame; and
generate the signal indicating the location of each energy storage module based on the detected magnetic field patterns.

20. The controller of claim 16, wherein the signals and energy storage module identifiers are coupled from the energy storage modules to the controller via a communications bus.
